(19) United States
(12) Patent Application Publication
(10) Pub. No.: US 2025/0042800 A1
(43) Pub. Date: Feb. 6, 2025

(54) GLASS ARTICLE AND DISPLAY DEVICE INCLUDING THE SAME

(71) Applicant: SAMSUNG DISPLAY CO., LTD., Yongin-Si (KR)

(72) Inventors: Seung Ho KIM, Yongin-Si (KR); Cheol Min Park, Yongin-Si (KR); Seung Kim, Yongin-Si (KR); Jin Su Nam, Yongin-Si (KR); Gyu In Shim, Yongin-Si (KR); Jae Gil Lee, Yongin-Si (KR); Jin Won Jang, Yongin-Si (KR); So Mi Jung, Yongin-Si (KR)

(21) Appl. No.: 18/629,930

(22) Filed: Apr. 8, 2024

(30) Foreign Application Priority Data
Jul. 31, 2023 (KR) 10-2023-0100092

(51) Int. Cl. C03C 3/04

(52) U.S. Cl. CPC C03C 3/04

(57) ABSTRACT

A glass article used as a cover glass of a flexible display device has values of indices consistent with results of a pen drop test and excellent impact resistance characteristics.

### CROSS-REFERENCE TO RELATED APPLICATION

This application claims priority under 35 U.S.C. 119 from Korean Patent Application No. 10-2023-0100092, filed on Jul. 31, 2023 in the Korean Intellectual Property Office, the contents of which are herein incorporated by reference in their entirety.

### TECHNICAL FIELD

Embodiments of the disclosure are directed to a glass article and a display device that includes the same.

### DISCUSSION OF THE RELATED ART

Glass articles are widely used in electronic devices or construction materials that include display devices. For example, glass articles can be incorporated into a substrate of a flat panel display device such as a liquid crystal display device (LCD), an organic light emitting display device (OLED), or an electrophoretic display device, or a cover window that protects the same.

As portable electronic devices such as smartphones and tablet PCs have become popular, glass articles used in them are frequently exposed to external impacts. Accordingly, a thin, portable glass article that can withstand external impacts is desirable.

In recent years, a foldable display device has been developed for user convenience. A glass article incorporated into a foldable display device should be thin to alleviate bending stress caused when folded and strong to withstand external impacts. Accordingly, attempts have been made to improve the strength of thin glass articles by changing the composition ratio of the glass articles and the manufacturing process conditions.

### SUMMARY

Embodiments of the disclosure provide a glass article whose indices defined as specific physical properties satisfy a predetermined value to have increased impact resistance characteristics, and a display device that includes the glass article.

The glass article according to one embodiment may have a fracture energy index, an elastic energy index, and a free volume index higher than or equal to a predetermined value, and thus has excellent impact resistance characteristics. A display device including the glass article may have excellent flexibility and strength due to the foldable characteristics of the glass article.

According to an embodiment of the disclosure, a glass article has a thickness that ranges from 20 μm to 150 μm, and has a first elastic energy index defined by the following Eq. 2-1 and that is equal to or greater than 0.8 MPa²/m^{0.5}.

$$First elastic energy index ( {E}_{elas 1} ) = ( 1 / B ) * {E}_{abs} , \qquad ( Eq . 2 - 1 )$$

where ‘B’ is a brittleness, and ‘E_{abs}’ is an absorption energy and is defined by a following Eq. A:

$$Absorption energy ( {E}_{abs} ) = {σ}^{2} * ( 1 - v ) / E , \qquad ( Eq . A )$$

where ‘σ’ is a surface strength and is defined by a following Eq. B:

$$Surface strength ( σ ) = ( E * α * {ρ}^{2} ) / ( 1 - v ) , \qquad ( Eq . B )$$

‘E’ is Young's modulus, ‘α’ is a thermal expansion coefficient, ‘ρ’ is a density, and ‘v’ is Poisson's ratio, and
a stretch index (β_{KWW}) defined by a following Eq. 2 is equal to or greater than 0.95:

$${β}_{KWW} = 1 - \sqrt{\frac{{( {T}_{0} - {T}_{g} )}^{2}}{D}} , \qquad ( 2 )$$

‘D’ is a strength factor (=B_{VFT}/T₀), ‘T₀’ is a Vogel temperature, and ‘T_{g}’ is a glass transition temperature.

The first elastic energy index may be equal to or greater than 0.9 MPa²/m^{0.5}.

A second elastic energy index defined by a following Eq. 2-2 may be equal to or greater than 0.1*10⁻⁴ (kJ/m²)²:

$$Second elastic energy index ( {E}_{elas 2} ) = {G}_{IC} * {( 1 / B )}^{6} * {E}_{abs} , \qquad ( Eq . 2 - 2 )$$

where ‘G_{IC}’ is a facture energy index according to a following Eq. 1, ‘B’ is a brittleness, and ‘E_{abs}’ is an absorption energy:

$$Fracture energy index ( {G}_{IC} ) = ( {K}_{IC}^{2} * ( 1 - {v}^{2} ) ) / E , \qquad ( Eq . 1 )$$

where ‘K_{IC}’ is a fracture toughness, ‘v’ is Poisson's ratio, and ‘E’ is Young's modulus

The second elastic energy index may be equal to or greater than 0.12*10⁻⁴ (kJ/m²)².

The facture energy index may be equal to or greater than 150 kJ/m².

A third elastic energy index defined by a following Eq. 2-3 may be equal to or greater than 2.1 MPa²/m^{0.5}.

$$Third elastic energy index ( {E}_{elas 3} ) = {G}_{IC} * ( 1 / B ) * {E}_{abs} , \qquad ( Eq . 2 - 3 )$$

where ‘G_{IC}’ is a facture energy index, ‘B’ is the brittleness, and ‘E_{abs}’ is the absorption energy.

The third elastic energy index may be equal to or greater than 2.3 MPa²/m^{0.5}.

A crack generation height a pen drop test performed with a pen having a ball diameter of 0.7 mm and a weight of 1.12 g may be equal to or greater than 6 cm.

The glass article may contain SiO₂, Al₂O₃, and at least one metal oxide, fluxes defined as a ratio of a content of a monovalent metal oxide to a content of a divalent metal oxide in the at least one metal oxide may be within a range of 7.0 to 8.5, and a ratio of a content of Al₂O₃ to a total content of the at least one metal oxide may be within a range of 0.3 to 0.4.

According to an embodiment of the disclosure, a glass article has a thickness that ranges from 20 μm to 150 μm, a first free volume index defined by a following Eq. 3-1 and that is equal to or greater than 0.001K⁻¹:

$$First free volume index ( {V}_{t 1} ) = 1 / {T}_{g} , \qquad ( Eq . 3 - 1 )$$

where ‘T_{g}’ is a glass transition temperature, and
stretch index (β_{KWW}) defined by a following Eq. 2 is equal to or greater than 0.95:

$${β}_{KWW} = 1 - \sqrt{\frac{{( {T}_{0} - {T}_{g} )}^{2}}{D}} , \qquad ( 2 )$$

‘D’ is a strength factor (=B_{VFT}/T₀), ‘T₀’ is a Vogel temperature, and ‘T_{g}’ is a glass transition temperature.

A second free volume index defined by a following Eq. 3-2 may be equal to or greater than 7.0*10⁻⁸ (kJ/m²)²/K:

$$Second free volume index ( {V}_{t 2} ) = {G}_{IC} * {( 1 / B )}^{6} * {E}_{abs} * ( 1 / {T}_{g} ) , \qquad ( Eq . 3 - 2 )$$

where ‘T_{g}’ is a glass transition temperature, ‘B’ is a brittleness, and ‘G_{IC}’ is a facture energy index defined by a following Eq. 1:

$$Fracture energy index ( {G}_{IC} ) = ( {K}_{IC}^{2} * ( 1 - {v}^{2} ) ) / E , \qquad ( Eq . 1 )$$

Where ‘K_{IC}’ is a fracture toughness, ‘v’ is Poisson's ratio, and ‘E’ is Young's modulus,
‘E_{abs}’ is an absorption energy and is defined by a following Eq. A:

$$Absorption energy ( {E}_{abs} ) = {σ}^{2} * ( 1 - v ) / E , \qquad ( Eq . A )$$

where ‘σ’ is a surface strength and is defined by a following Eq. B:

$$Surface strength ( σ ) = ( E * α * {ρ}^{2} ) / ( 1 - v ) , \qquad ( Eq . B )$$

where ‘E’ is Young's modulus, ‘α’ is a thermal expansion coefficient, ‘ρ’ is a density, and ‘v’ is Poisson's ratio.

The second free volume index may be equal to or greater than 10.0*10⁻⁸ (kJ/m²)²/K.

A third free volume index defined by a following Eq. 3-3 may be equal to or greater than 6.0*10⁻¹⁴ MPa⁴/(m^{2.5}*K³):

$$Third free volume index ( {V}_{t 3} ) = {G}_{IC} * ( 1 / B ) * {E}_{abs} * σ * ( 1 / {( {T}_{g} )}^{3} ) , \qquad ( Eq . 3 - 3 )$$

where ‘T_{g}’ is a glass transition temperature, ‘G_{IC}’ is a facture energy index, ‘B’ is the brittleness, ‘E_{abs}’ is the absorption energy, and ‘σ’ is the surface strength.

The third free volume index may be equal to or greater than 9.0*10⁻¹⁴ MPa⁴/(m^{2.5}*K³).

According to an embodiment of the disclosure, a display device comprises a display panel that includes a plurality of pixels, a cover window disposed above the display panel, and an optically transparent bonding layer disposed between the display panel and the cover window. The cover window comprises a glass article whose thickness ranges from 20 μm to 100 μm, whose first elastic energy index defined by the following Eq. 2-1 is equal to or greater than 0.8 MPa²/m^{0.5}.

First elastic energy index (Eₑₗₐₛ₁)=(1/B)*E_{abs} (Eq. 2-1)
where ‘B’ is a brittleness, and ‘E_{abs}’ is an absorption energy and is defined by a following Eq. A:

$$Absorption energy ( {E}_{abs} ) = {σ}^{2} * ( 1 - v ) / E , \qquad ( Eq . A )$$

where ‘σ’ is a surface strength and is defined by a following Eq. B:

$$Surface strength ( σ ) = ( E * α * {ρ}^{2} ) / ( 1 - v ) , \qquad ( Eq . B )$$

where ‘E’ is Young's modulus, ‘α’ is a thermal expansion coefficient, ‘ρ’ is a density, and ‘v’ is Poisson's ratio, and
whose first free volume index defined by a following Eq. 3-1 is equal to or greater than 0.001K⁻¹:

$$First free volume index ( {V}_{t 1} ) = 1 / {T}_{g} \qquad ( Eq . 3 - 1 )$$

where ‘T_{g}’ is a glass transition temperature, and
whose stretch index (β_{KWW}) defined by a following Eq. 2 is equal to or greater than 0.95:

$${β}_{KWW} = 1 - \sqrt{\frac{{( {T}_{0} - {T}_{g} )}^{2}}{D}} , \qquad ( 2 )$$

where ‘D’ is a strength factor (=B_{VFT}/T₀), ‘T₀’ is a Vogel temperature, and ‘T_{g}’ is a glass transition temperature.

### BRIEF DESCRIPTION OF THE DRAWINGS

FIG. 1 is a perspective view of a glass article according to various embodiments.

FIG. 2 is a perspective view of an unfolded display device that incorporates a glass article according to an embodiment.

FIG. 3 is a perspective view of a folded display device of FIG. 2.

FIG. 4 is a cross-sectional view of an example in which a glass article according to an embodiment is used as a cover window of a display device.

FIG. 5 is a cross-sectional view of a glass article that has a flat plate shape, according to an embodiment.

FIG. 6 is a graph showing a stress profile of a glass article as a function of thickness, according to an embodiment.

FIG. 7 is a flowchart of a process for fabricating a glass article according to an embodiment.

FIG. 8 is a diagram that illustrates the steps of FIG. 7, from a cutting step to a surface polishing step after strengthening.

FIG. 9 illustrates a pen drop test method of a glass article specimen according to an embodiment.

### DETAILED DESCRIPTION

Embodiments of the disclosure will now be described more fully hereinafter with reference to the accompanying drawings. Embodiments of the disclosure may, however, take different forms and should not be construed as limited to embodiments set forth herein.

It will also be understood that when a layer is referred to as being “on” another layer or substrate, it can be directly on the other layer or substrate, or intervening layers may also be present. The same reference numbers may indicate the same components throughout the specification.

Hereinafter, embodiments will be described with reference to the accompanying drawings.

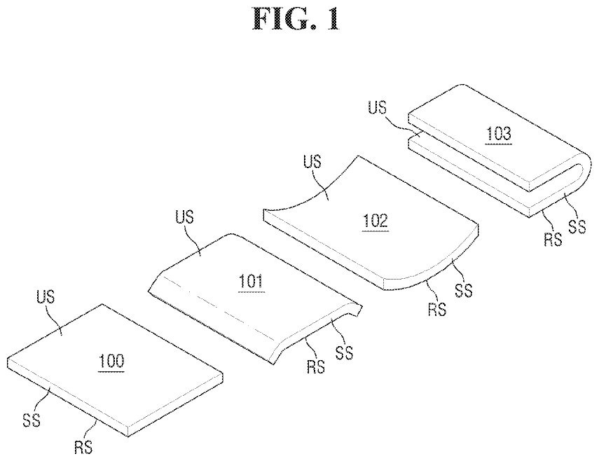

FIG. 1 is a perspective view of a glass article according to various embodiments.

Glass can be used as a cover window for protecting a display, a substrate for a display panel, a substrate for a touch panel, an optical member such as a light guide plate, etc., in electronic devices that include a display, such as a tablet PC, a notebook PC, a smartphone, an electronic book, a television and a PC monitor as well as a refrigerator or a cleaning machine that includes a display screen. Glass can also be used as a cover glass for a dashboard of a vehicle, a cover glass for solar cells, interior materials for construction materials, windows for buildings and houses, etc.

Glass should have high strength. For example, when glass is used as a window, to the glass should be thin for high transmittance and lightweight, and also have strength to withstand external impacts. Strengthened glass can be produced by, for example, chemical strengthening or thermal strengthening. Examples of strengthened glass that have various shapes are shown in FIG. 1.

Referring to FIG. 1, in an embodiment, a glass article 100 may have a flat sheet or a flat plate shape. In other embodiments, glass articles 101, 102 and 103 have a three-dimensional shape that includes bent portions. For example, the edges of the flat portion may be bent, such as the glass article 101, or the flat portion may be entirely curved, such as the glass article 102, or folded, such as the glass article 103. In other embodiments, the glass article 100 has a flat sheet or flat plate shape, and can be flexibly folded, stretched, or rolled.

The planar shape of the glass articles 100 to 103 may be a rectangular shape, but is not necessarily limited thereto, and may have various other shapes, such as a rectangular shape with rounded corners, a square shape, a circular shape, or an elliptical shape. In an embodiment, a flat plate that has a rectangular planar shape is described as an example of the glass articles 100 to 103, but embodiments of the disclosure are not necessarily limited thereto.

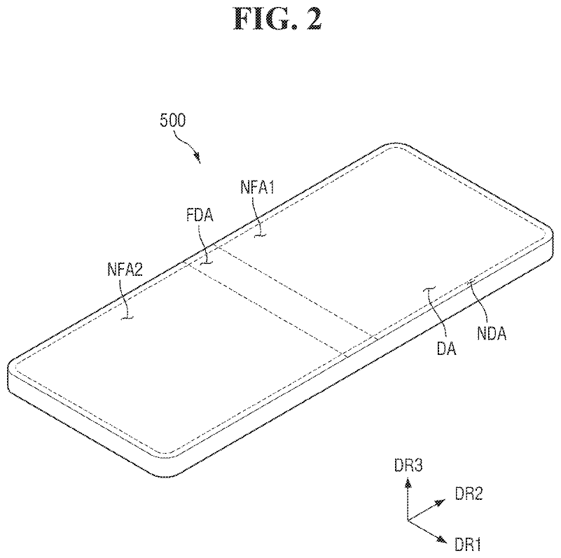

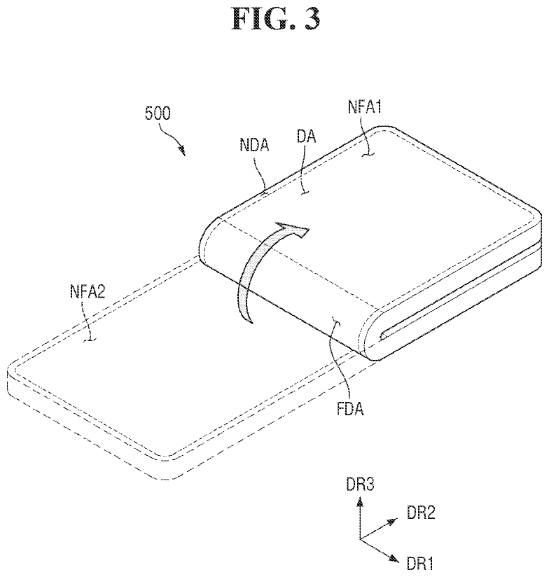

FIG. 2 is a perspective view of an unfolded display device that incorporates a glass article according to an embodiment. FIG. 3 is a perspective view showing a folded display device of FIG. 2.

Referring to FIGS. 2 and 3, a display device 500 according to an embodiment is a foldable display device. As will be described below, in the display device 500, the glass article 100 of FIG. 1 can be used as a cover window, and the glass article 100 may be flexible and/or foldable.

In FIGS. 2 and 3, a first direction DR1 is a direction parallel to a first side of the display device 500 in a plan view and may be, for example, a horizontal direction of the display device 500. A second direction DR2 is a direction parallel to a second side in contact with the first side of the display device 500 in a plan view, and may be, for example, a vertical direction of the display device 500. A third direction DR3 is a thickness direction of the display device 500.

In an embodiment, the display device 500 has a rectangular shape in a plan view. The display device 500 has a rectangular shape with right-angled or rounded corners in a plan view. The display device 500 includes two short sides that extends in the first direction DR1 and two long sides that extend in the second direction DR2 in a plan view.

The display device 500 includes a display area DA and a non-display area NDA. In a plan view, the shape of the display area DA corresponds to the shape of the display device 500. For example, when the display device 500 has a rectangular shape in a plan view, the display area DA also has a rectangular shape.

The display area DA includes a plurality of pixels that can display an image. The plurality of pixels are arranged in a matrix. The plurality of pixels may have one of a rectangular, rhombic, or square shape in a plan view, without necessarily being limited thereto. For example, the plurality of pixels may have a quadrilateral shape other than a rectangular, rhombic, or square shape, a polygonal shape other than a quadrilateral shape, a circular shape, or an elliptical shape.

The non-display area NDA does not include pixels and does not display an image. The non-display area NDA is disposed around the display area DA. The non-display area NDA surrounds the display area DA, but is not necessarily limited thereto. The display area DA may be partially surrounded by the non-display area NDA.

In an embodiment, the display device 500 can maintain both a folded state and an unfolded state. As shown in FIG. 3, the display device 500 can be folded in an in-folding manner in which the display area DA is disposed on the inside thereof. When the display device 500 is in-folded, the top surfaces of the display device 500 face each other. For another example, the display device 500 can be folded in an out-folding manner in which the display area DA is disposed on the outside. When the display device 500 is out-folded, the bottom surfaces of the display device 500 face each other.

In an embodiment, the display device 500 is a foldable device. As used herein, the term “foldable device” refers to a device that can be folded and refers not only to a folded device but also a device that can have both a folded state and an unfolded state. Further, “folding” can include folding at an angle of about 180 degrees. However, embodiments of the disclosure are not necessarily limited thereto, and it can include an embodiment where the folding angle exceeds 180 degrees or is less than 180 degrees, such as an embodiment where the folding angle is equal to or greater than 90 degrees and less than 180 degrees, or an embodiment where the folding angle is equal to or greater than 120 degrees and less than 180 degrees. In addition, a folded state can refer to a state in which folding is performed from an unfolded state, even if complete folding is not performed. For example, even if the display device 500 is folded at an angle of 90 degrees or less, as long as the maximum folding angle becomes 90 degrees or more, the display device 500 may be expressed as being in a folded state to distinguish it from the unfolded state. During folding, the radius of curvature may be 5 mm or less, in a range of 1 mm to 2 mm, or about 1.5 mm, but is not necessarily limited thereto.

In an embodiment, the display device 500 includes a foldable area FDA, a first non-foldable area NFA1, and a second non-foldable area NFA2. The foldable area FDA is where the display device 500 is folded, and the first and second non-foldable areas NFA1 and NFA2 are areas in which the display device 500 is not folded.

The first non-foldable area NFA1 is disposed on one side, such as an upper side, of the foldable area FDA. The second non-foldable area NFA2 is disposed on another side, such as a lower side, of the foldable area FDA. The foldable area FDA can be bent with a predetermined curvature.

In an embodiment, the foldable area FDA of the display device 500 is located at a specific location. In other embodiments, two or more foldable areas FDA are located at a specific location(s) in the display device 500. In another embodiment, the location of the foldable area FDA is not specified in the display device 500 and can be freely set in various areas.

In an embodiment, the display device 500 is folded in the second direction DR2. Accordingly, the length of the display device 500 in the second direction DR2 is reduced to approximately half, so that a user can conveniently carry the display device 500.

In an embodiment, the direction in which the display device 500 is folded is not necessarily limited to the second direction DR2. For example, in an embodiment, the display device 500 can be folded in the first direction DR1. In this embodiment, the length of the display device 500 in the first direction DR1 is reduced to approximately half.

It is illustrated in the drawing that each of the display area DA and the non-display area NDA overlaps the foldable area FDA, the first non-foldable area NFA1, and the second non-foldable area NFA2, but the disclosure is not limited thereto. For example, each of the display area DA and the non-display area NDA may overlap at least one of the foldable area FDA, the first non-foldable area NFA1, and the second non-foldable area NFA2.

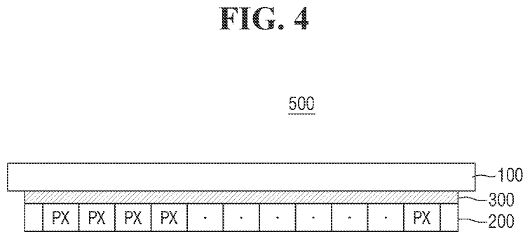

FIG. 4 is a cross-sectional view of an example in which a glass article according to an embodiment is used as a cover window of a display device.

Referring to FIG. 4, in an embodiment, the display device 500 includes a display panel 200, a glass article 100 disposed on the display panel 200 and that serves as a cover window, and an optically transparent bonding layer 300 disposed between the display panel 200 and the glass article 100 that bonds the display panel 200 and the glass article 100 to each other.

Examples of the display panel 200 include not only a self-light emitting display panel such as an organic light emitting display (OLED) panel, an inorganic electroluminescence (EL) display panel, a quantum dot light emitting display (QED) panel, a micro-LED display panel, a nano-LED display panel, a plasma display panel (PDP), a field emission display (FED) panel or a cathode ray tube (CRT) display panel, but also a light receiving display panel such as a liquid crystal display (LCD) panel or an electrophoretic display (EPD) panel.

The display panel 200 includes a plurality of pixels PX and displays an image by using light emitted from each pixel PX. The display device 500 further includes a touch member. In an embodiment, the touch member is embedded in the display panel 200. For example, since the touch member is directly formed on a display member of the display panel 200, the display panel 200 itself can perform a touch function. In an embodiment, the touch member is separately manufactured from the display panel 200 and then attached to the top surface of the display panel 200 by an optically transparent bonding layer.

The glass article 100 is disposed above the display panel 200 and protects the display panel 200. Since the glass article 100 is larger in size than the display panel 200, the side surface thereof protrudes outward from the side surface of the display panel 200, but is not necessarily limited thereto. The display device 500 further includes a printed layer disposed on at least one surface of the glass article 100 at an edge portion of the glass article 100. The printed layer prevents the bezel area of the display device 500 from being externally visible, and may be decorative in some cases.

The optically transparent bonding layer 300 is disposed between the display panel 200 and the glass article 100. The optically transparent bonding layer 300 fixes the glass article 100 onto the display panel 200. The optically transparent bonding layer 300 includes one or more of an optically clear adhesive (OCA) or an optically clear resin (OCR), etc.

Hereinafter, the strengthened glass article 100 will be described in more detail.

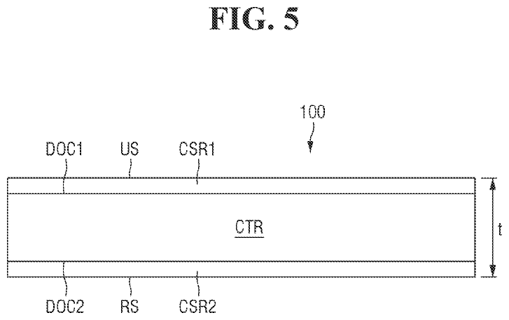

FIG. 5 is a cross-sectional view of a glass article that has a flat plate shape according to an embodiment.

Referring to FIG. 5, in an embodiment, the glass article 100 includes a first surface US, a second surface RS and a side surface. In the flat plate shaped glass article 100, the first surface US and the second surface RS have a large area, and the side surface are outer surfaces that connect the first surface US with the second surface RS.

The first surface US and the second surface RS are opposite to each other in a thickness direction. When the glass article 100 transmits light like a cover window of a display, the light is mainly incident on one of the first surface US or the second surface RS and passes through to the other surface.

A thickness t of the glass article 100 is defined as a distance between the first surface US and the second surface RS. The thickness t of the glass article 100 may be 150 μm or less, or may be within a range of 20 μm to 150 μm, but not necessarily limited thereto. In an embodiment, the thickness t of the glass article 100 is 100 μm or less. In an embodiment, the thickness t of the glass article 100 is 80 μm or less. In an embodiment, the thickness t of the glass article 100 is about 70 μm or less. In an embodiment, the thickness t of the glass article 100 is about 60 μm or less. In an embodiment, the thickness t of the glass article 100 is about 65 μm or less. In an embodiment, the thickness t of the glass article 100 is about 50 μm or less. In an embodiment, the thickness t of the glass article 100 is about 30 μm or less. In some embodiments, the thickness t of the glass article 100 is within a range of 20 μm to 50 μm, or is about 30 μm. In an embodiment, the glass article 100 has a uniform thickness t, but is not necessarily limited thereto, and other embodiments has a different thickness t for each region.

The glass article 100 is strengthened to have a predetermined stress profile. The strengthened glass article 100 more efficiently prevents generation of cracks, propagation of cracks, breakage, etc., due to external impacts than the un-strengthened glass article 100. The strengthened glass article 100 may have a different stress for each region. For example, compressive regions CSR1 and CSR2 to which a compressive stress is applied are formed in the vicinity of the surface of the glass article 100, such as near the first surface US and the second surface RS, and a tension region CTR to which a tensile stress is applied is formed inside the glass article 100. Boundaries DOC1 and DOC2 between the compressive regions CSR1 and CSR2 and the tensile region CTR have a stress value of zero. The compressive stress in one of the compressive regions CSR1, CSR2 varies in its stress value depending on position, such as a depth from the surface. In addition, the tensile region CTR has a different stress values depending on the depth from the surfaces US, RS.

The position of the compressive region CSR1, CSR2, the stress profile in the compressive region CSR1, CSR2, the compressive energy of the compressive region CSR1, CSR2, the tensile energy of the tensile region CTR, etc., in the glass article 100 has a great influence on the mechanical properties of the glass article 100, such as surface strength.

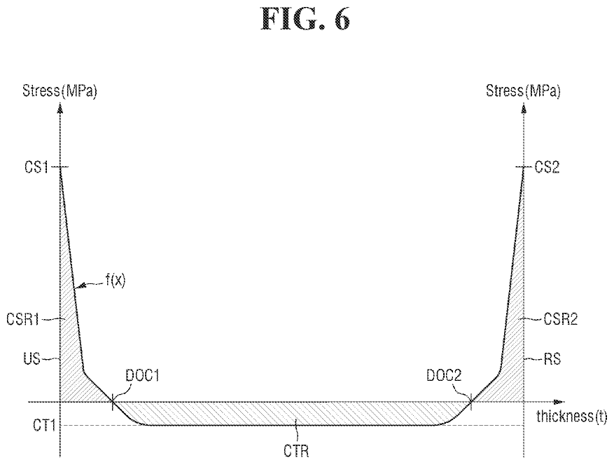

FIG. 6 is a graph showing a stress profile of a glass article as a function of thickness, according to one embodiment. In the graph of FIG. 6, an X-axis represents the thickness direction of the glass article. In FIG. 6, the compressive stress has positive values, while the tensile stress has negative values. The magnitude of the compressive/tensile stress is the magnitude of an absolute value regardless of its sign.

Referring to FIG. 6, in an embodiment, the glass article 100 includes a first compressive region CSR1 that extends from the first surface US to a first compression depth DOL1, and a second compressive region CSR2 that extends from the second surface RS to a second compression depth DOL2. The tensile region CTR extends between the first compression depth DOL1 and the second compression depth DOL2. The overall stress profile in the glass article 100 is symmetrical with respect to the center of the direction of the thickness t. Although not shown in FIG. 6, a compressive region and a tensile region are similarly formed between opposite side surfaces of the glass article 100.

The first compressive region CSR1 and the second compressive region CSR2 are resistant to an external impact and prevent the generation of cracks or breakage of the glass article 100. As the maximum compressive stresses CS1 and CS2 of the first compressive region CSR1 and the second compressive region CSR2 are greater after the strengthening process, the strength of the glass article 100 generally increases. Since an external impact is usually transmitted through the surface of the glass article 100, the maximum compressive stresses CS1 and CS2 should be at the surface of the glass article 100 in terms of durability. From this perspective, the compressive stress of the first compressive region CSR1 and the second compressive region CSR2 tends to be greatest at the surface and generally decreases toward the inside.

The first compression depth DOC1 and the second compression depth DOC2 suppress cracks or grooves formed in the first surface US and the second surface RS from propagating into the tensile region CTR inside the glass article 100. As the first compression depth DOC1 and the second compression depth DOC2 are greater after the strengthening process, cracks, etc., can be more efficiently prevented from propagating. The points that correspond to the first compression depth DOC1 and the second compression depth DOC2 correspond to a boundary between the compressive regions CSR1 and CSR2 and the tension region CTR, and have a stress value of zero.

Throughout the glass article 100, the tensile stress of the tensile region CTR is balanced with the compressive stress of the compressive regions CSR1 and CSR2. For example, the total compressive stress, such as the total compressive energy, in the glass article 100 is the same as the total tensile stress, such as a total tensile energy, in the glass article 100. The stress energy that accumulates in a region of the glass article 100 that has a constant width in the thickness t direction can be calculated as an integrated value of the stress profile. The following Mathematical Expression 1 expresses the stress profile in the glass article 100 of thickness t as a function f(x).

$${\int }_{0}^{t} f ( x ) dx = 0 \qquad Mathematical Expression 1$$

The greater the magnitude of the tensile stress in the glass article 100, the more likely are fragments to shatter when the glass article 100 is broken, and the more likely the glass article 100 is to be broken from the inside. The maximum tensile stress that meets the frangibility requirements of the glass article 100 satisfies, but is not necessarily limited to, the following Mathematical Expression 2.

$${CT}_{1} \leq - 38.7 \times ln ( t ) + 48.2 \qquad Mathematical Expression 2$$

In some embodiments, the maximum tensile stress CT1 is 100 MPa or less, or 85 MPa or less. A maximum tensile stress CT1 of 75 MPa or more increases mechanical properties such as strength. In an embodiment, the maximum tensile stress CT1 is greater than or equal to 75 MPa and less than or equal to 85 MPa, but is not necessarily limited thereto.

The maximum tensile stress CT1 of the glass article 100 is generally located at a central portion in the thickness t direction of the glass article 100. For example, the maximum tensile stress CT1 of the glass article 100 is located at a depth in the range of 0.4t to 0.6t, or in the range of 0.45t to 0.55t, or at a depth of about 0.5t.

In addition, to increase the strength of the glass article 100, the compressive stress and the compression depths DOC1 and DOC2 should have large values. However, as the compressive energy increases, the tensile energy also increases, and the maximum tensile stress CT1 increases. To meet the fragility requirements while having a high strength, the stress profile should be adjusted such that the maximum compressive stresses CS1 and CS2 and the compression depths DOL1 and DOL2 have large values while the compressive energy decreases. To this end, the glass article 100 is manufactured using a glass composition that contains specific components at a predetermined content. Depending on the composition ratio of the components in the glass composition, the manufactured glass article 100 has excellent strength, flexibility and physical properties so as to be incorporated into a foldable display device.

In accordance with an embodiment, the glass composition of the glass article 100 includes one or more of SiO₂, Al₂O₃, Na₂O, Li₂O, CaO or MgO, and ZrO₂.

SiO₂ constitute the skeleton of glass, and increases chemical durability and reduces the generation of cracks when scratches (indentations) are formed on the glass surface. SiO₂ forms the network of the glass, and the manufactured glass article 100 that contains SiO₂ has a reduced thermal expansion coefficient and increased mechanical strength.

Al₂O₃ increases the breakage resistance of glass. For example, Al₂O₃ generates a smaller number of fragments when the glass breaks. Al₂O₃ is an intermediate oxide that forms a bond with SiO₂ to form a network structure. In addition, Al₂O₃ is an active component that increases ion exchange performance during chemical strengthening and increases surface compressive stress after strengthening.

Na₂O forms surface compressive stress by ion exchange and increases the meltability of glass. Na₂O forms non-bridging oxygen in the SiO₂ network structure by forming an ionic bond with oxygen of the SiO₂ that forms the network structure. The increase in the non-bridging oxygen increases the flexibility of the network structure, and the glass article 100 has physical properties suitable for a foldable display device.

Similarly to the above-described Na₂O, Li₂O forms surface compressive stress by ion exchange and increases the meltability of glass. Li₂O forms non-bridging oxygen in the SiO₂ network structure by forming an ionic bond with the oxygen of the SiO₂ that forms the network structure. The increase in the non-bridging oxygen increases the flexibility and impact absorption function of the network structure, and the glass article 100 has physical properties suitable for a foldable display device.

MgO increases the surface strength of glass and reduces the formation temperature of glass. MgO is a network modifier oxide that modifies the SiO₂ network structure that forms the network structure. MgO reduces the refractive index of glass and adjusts the thermal expansion coefficient and elastic modulus of glass. CaO increases the surface strength of glass. CaO is a network modifier oxide that modifies the SiO₂ network structure that forms the network structure. CaO increases the glass transition temperature of glass and increases chemical durability.

ZrO₂ increases the transmittance and surface strength of glass and increases resistance to surface crack propagation. ZrO₂ is an intermediate oxide that forms a bond with that SiO₂ that forms a network structure. ZrO₂ bonds to a part where bonds are broken by Li₂O and Na₂O in the SiO₂ network structure, thereby increasing the fracture toughness of glass and increasing the repulsive force against bending.

In addition to the components mentioned above, the glass composition may further include components such as P₂O₅, B₂O₃, K₂O, Y₂O₃, La₂O₃, Nb₂O₅, Ta₂O₅, or Gd₂O₃, etc., as necessary. In addition, a small amount of Sb₂O₃, CeO₂, SnO₂, and/or As₂O₃ may be further included as a clarifying agent.

The glass article 100 manufactured using the glass composition according to an embodiment has characteristics and physical properties suitable for a foldable display device. For example, the glass article 100 is flexible to be folded and unfolded, and has strength and chemical properties suitable for use as a cover window of the display device 500. Further, the glass composition is flexible so that the glass article 100 can be folded and unfolded. The folding and unfolding characteristics of the glass article 100 are increased by reducing the glass transition temperature and elastic modulus of glass. For example, as the elastic modulus of glass is reduced, the stress applied to the lower portion of the glass article during folding and unfolding is reduced, thereby increasing the bending characteristics of the glass article. Further, impact resistance characteristics can be increased by lowering the elastic modulus that is inversely proportional to the probability of molecular vibration in the case of impacts and increasing free volume fraction that is proportional to impact energy.

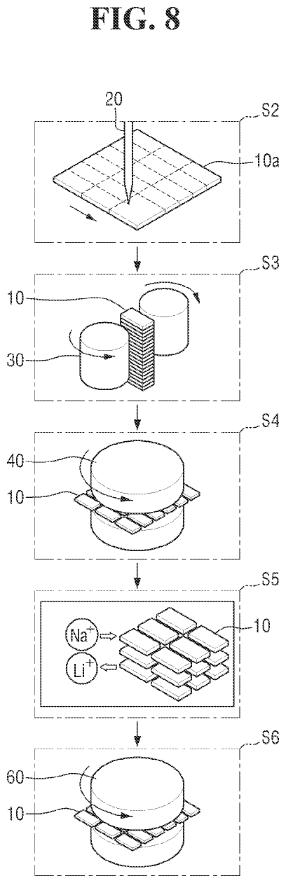

The glass article 100 according to an embodiment can be manufactured using the glass composition by a manufacturing process to be described below with reference to FIG. 8. The glass article 100 is further subjected to a quenching process and a strengthening process in the manufacturing process to be described below to have increased impact resistance characteristics. The physical properties of the glass article 100 that are related to an intermolecular bonding strength can be enhanced depending on the types and composition ratios of the components of the glass composition. Further, the physical properties of the glass article 100, such as density, fracture toughness, and brittleness, can be further enhanced by the quenching process, and the physical properties of the glass article 100, such as a strengthening stress, a glass transition temperature related to a stress depth, Young's modulus, density, hardness, and brittleness, can be further enhanced by a chemical strengthening process. The glass article 100 according to an embodiment has excellent impact resistance characteristics due to the quenching process and the strengthening process performed during the manufacturing process, and, for example, has physical properties and characteristics suitable for the foldable display device 500.

A glass composition that has the above composition can be molded into a plate glass shape by various methods known in the art. When the glass composition is molded into a plate glass shape, the glass composition can be further processed and manufactured into the glass article 100 suitable for the display device 500. However, embodiments of the disclosure are not necessarily limited thereto, and the glass composition might not be molded into a plate glass shape and may be directly molded into the glass article 100 suitable for a product without an additional molding process.

Hereinafter, a process in which a glass composition is molded into a plate glass shape and processed into the glass article 100 will be described.

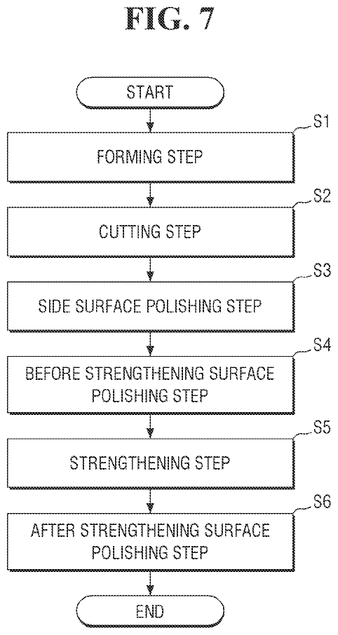

FIG. 7 is a flowchart of the steps of a process for fabricating a glass article according to an embodiment. FIG. 8 is a diagram that illustrates the steps of FIG. 7 from a cutting step to a surface polishing step after strengthening.

Referring to FIGS. 7 and 8, in an embodiment, a method for producing the glass article 100 includes a molding step S1, a cutting step S2, a side polishing step S3, a before strengthening surface polishing step S4, and a strengthening step S5, and an after strengthening surface polishing step S6.

The molding step S1 includes preparing a glass composition and molding the glass composition. The glass composition has the composition and components as described above, and thus a repeated detailed description thereof is omitted. The glass composition is molded into a plate glass shape by a method such as one of a float process, a fusion draw process, or a slot draw process, etc.

The glass molded into a flat plate shape is cut in the cutting step S2. The glass molded into a flat plate shape has a different size than that of the final glass article 100. For example, glass molding is performed to form a large-area substrate as a parent substrate 10a that includes a plurality of glass articles. The parent glass substrate 10a is cut into a plurality of cells 10 to produce a plurality of glass articles. For example, even though the final glass article 100 has a size of about 6 inches, when glass is molded to have a size of several to several hundred times that large, e.g., 120 inches and then cut, 20 glass articles molded into a flat plate shape are obtained at once. In this way, process efficiency is increased as compared with separately molding an individual glass article. In addition, even when molding a glass that corresponds to the size of one glass article, if the final glass article has one of various planar shapes, it can be made into a desired shape through a cutting process.

Cutting the glass 10a is performed using a cutting knife 20, a cutting wheel, a laser, etc.

The cutting step S2 is performed before the strengthening step S5. The parent glass substrate 10a may be strengthened at once and then cut into the size of the final glass article. However, in this case, the cut surface. such as the side surface of glass, is put in a non-strengthened state. Accordingly, the strengthening step S5 is performed after cutting is completed.

Between the cutting step S2 and the strengthening step S5 of glass, a before strengthening polishing step is performed. The polishing step includes the side polishing step S3 and the surface polishing step S4. In an embodiment, after the side polishing step S3 is performed, the before strengthening surface polishing step S4 is performed, but embodiments are not necessarily limited thereto, and in an embodiment, this order is reversed.

The side polishing step S3 polishes the side surfaces of the cut glass 10. In the side polishing step S3, the side surfaces of the glass 10 are polished to have a smooth surface. Further, each side surface of the glass 10 has a uniform surface through the side polishing step S3. For example, the cut glass 10 includes one or more cut surfaces. In some cut glasses 10, two of four side surfaces are cut surfaces. In some other cut glasses 10, three of four side surfaces are cut surfaces. In some other cut glasses 10, all four side surfaces are cut surfaces. When a side surface is a cut surface, it has a different surface roughness from that of an uncut surface. In addition, even the cut surfaces may have different surface roughness. Therefore, by polishing each side surface through the side polishing step S3, each side surface has a uniform surface roughness, etc. Further, small cracks that may be present on the side surface are removed through the side polishing step S3.

The side polishing step S3 may be performed simultaneously on a plurality of cut glasses 10. For example, when the plurality of cut glasses 10 are stacked, the stacked glasses 10 can be polished at the same time.

The side polishing step S3 can be performed by one of a mechanical polishing method or a chemical mechanical polishing method using a polishing apparatus 30. In an embodiment, two opposite side surfaces of the cut glasses 10 are polished simultaneously, and then the other two opposite side surfaces are polished simultaneously, but embodiments of the disclosure are not necessarily limited thereto.

The before strengthening surface polishing step S4 is performed such that each glass 10 has a uniform surface. The before strengthening surface polishing step S4 may be performed separately for each cut glass 10. However, when a chemical mechanical polishing apparatus 40 is sufficiently large compared to the glass 10, the plurality of glasses 10 are horizontally arranged and then surface-polished simultaneously.

The before strengthening surface polishing step S4 is performed by chemical mechanical polishing. For example, the first and second surfaces of the cut glass 10 are polished using the chemical mechanical polishing apparatus 40 and a polishing slurry. In an embodiment, the first surface and the second surface are polished simultaneously. In an embodiment, one of the first and second surfaces is polished and then the other surface is polished.

After the before strengthening polishing step S4, the strengthening step S5 is performed. The strengthening step S5 includes chemical strengthening and/or thermal strengthening. When the glass 10 has a thickness of 2 mm or less, such as about 0.75 mm or less, a chemical strengthening method is appropriately used for precise stress profile control.

After the strengthening step S5, selectively, the after strengthening surface polishing step S6 is further performed. The after strengthening surface polishing step S6 removes fine cracks on the surface of the strengthened glass 10 and controls compressive stress of the first surface and the second surface of the strengthened glass 10. For example, a floating method, which is one of methods for manufacturing a glass plate, is performed by flowing a glass composition into a tin bath. For example, the surface of the glass plate in contact with the tin bath has different compositions from the surface not in contact with the tin bath. As a result, after the strengthening step S5 of the glass 10, deviations in compressive stress can occur between the surface in contact with the tin bath and the surface not in contact with the tin bath. However, by removing the surface of the glass 10 to an appropriate thickness by polishing, deviations in compressive stress between the contact surface and the non-contact surface can be reduced.

The after strengthening surface polishing step S6 is performed by a chemical mechanical polishing method. For example, the first and second surfaces of the strengthened glass 10 are polished using a chemical mechanical polishing apparatus 60 and a polishing slurry. The polishing thickness can be adjusted, for example, to be in the range of 100 nm to 1000 nm, but is not necessarily limited thereto. The polishing thicknesses of the first surface and the second surface may be the same, or may be different.

In addition, after the after strengthening surface polishing step S6, a shape machining process may be further performed as necessary. For example, when manufacturing the glass articles 101 to 103 that have the three-dimensional shapes shown in FIG. 1, a three-dimensional machining process is performed after the after strengthening surface polishing step S6.

As described above, the glass article 100 manufactured by an above process can be used as a cover window of the foldable display device 500. The glass article 100 is flexible and foldable. Further, the glass article 100 has impact resistance characteristics suitable for use as a cover window.

The impact resistance characteristics of the glass article 100 are related to various mechanical and chemical properties of the glass article 100. For example, the glass article 100 has properties such as a thermal expansion coefficient, a transition temperature, a density, a Young's modulus, a Poisson's ratio, a Vickers hardness, a fracture toughness, a brittleness, etc. The physical properties are measurable in a specimen of the glass article 100. In general, the glass article 100 has excellent impact resistance characteristics when values of the physical properties exceed a certain level, but the reference values thereof may be unclear. For example, when comparing the physical properties of various glass articles 100, it may be challenging to determine whether the glass article 100 whose specific physical properties have relatively high values necessarily has better resistance to external impacts than other glass articles 100. It means that various physical properties of the glass article 100 need to be comprehensively evaluated to determine whether or not it has excellent impact resistance characteristics, the impact resistance properties of the glass article 100 cannot be determined by the measurable physical properties of the glass article 100. For example, when the glass article 100 is used as the cover window of the display device 500, the correlation between the impact resistance characteristics of the glass article 100 and the values of the physical properties of the glass article 100 may be unclear.

A pen drop test can be used as one of the indicators for evaluating the impact resistance characteristics of the glass article 100. When preparing various glass articles 100 as specimens and performing the pen drop test, the impact resistance characteristics of the glass article 100 can be determined by the height of the pen at which cracks or damages start to occur in the glass article specimens. For example, the pen drop test result may be a better criterion for evaluating the impact resistance characteristics of the glass article 100 rather than the values of the physical properties of the glass article 100.

In addition, whether or not the glass article 100 is damaged is affected by upper damage and lower damage in the area to which an impact is applied and structural changes of molecules that constitute the glass article 100. If the glass article 100 has high resistance to upper damage and lower damage, the glass articles 100 is likely to withstand external impacts. If there is a free space between molecules that constitute the glass article 100, the molecular structure can change easily and the glass article 100 is likely to withstand external impacts.

Major factors for damage resistance and the molecular structure of the glass article 100 are fracture energy and elastic energy of the glass article 100, and a free volume derived therefrom. The fracture energy and the elastic energy include the above-described physical properties of the glass article 100 as the major factors, and the free volume includes the facture energy and the elastic energy as major factors. In the glass article 100, the factors related to the fracture energy, the elastic energy, and the free volume that are derived from the above-described physical properties can be defined.

In accordance with an embodiment, the glass article 100 has factors that are quantifiable and derived as measurable physical properties, and the quantified factors are consistent with the pen drop test result that is the clear criterion for impact resistance characteristics. Therefore, the pen drop test result and the impact resistance characteristics of the glass article 100 are determined by the values of specific factors, and the impact resistance characteristics of the glass article 100 can be increased by adjusting the values of the corresponding factors. The glass article 100 has increased pen drop characteristics, that is, impact resistance characteristics, because specific factors to be described below have a certain value or more. Hereinafter, various factors that are consistent with the pen drop test result include factors that can be derived from the measurable physical properties of the glass article 100.

The facture energy index of the glass article 100, which is a factor of a bonding strength or resistance to upper damage against external impacts, can be defined by the following Eq. 1.

$$Fracture energy index ( {G}_{IC} ) = ( {{K}_{IC}}^{2} * ( 1 - {v}^{2} ) ) / E ( kJ / {m}^{2} ) \qquad ( Eq . 1 )$$

In Eq. 1, ‘K_{IC}’ is fracture toughness, ‘v’ is Poisson's ratio, and ‘E’ is Young's modulus. The unit of the facture energy index G_{IC} in Eq. 1 is ‘kJ/m²’. The ‘K_{IC}’, ‘v’, and ‘E’ values can be expressed in units of ‘kJ/m²’.

The fracture energy index of the glass article 100 is the factor related to the resistance to upper imprinting damage from external impacts. The fracture energy index increases as the fracture toughness increases and the Poisson's ratio and the Young's modulus decrease. For example, as the fracture toughness increases and the Poisson's ratio and the Young's modulus decrease, the glass article 100 has an increased fracture energy index value, and increased bonding strength and resistance to upper damage from external impacts. For example, the glass article 100 has a fracture energy index of 150 kJ/m² or more according to Eq. 1.

In accordance with an embodiment, the first elastic energy index of the glass article 100 is defined by the following Eq. 2-1.

$$First elastic energy index ( {E}_{elas 1} ) = ( 1 / B ) * {E}_{abs} ( MPa / {m}^{1.5} ) \qquad ( Eq . 2 - 1 )$$

In Eq. 2-1, ‘B’ is brittleness (facture toughness K_{IC}/hardness Hv m^{0.5}), ‘E_{abs}’ is absorption energy, and the unit of the first elastic energy index may be ‘MPa/m^{0.5}’. In Eq. 2-1, ‘B’ and ‘E_{abs}’ values are expressed ion units of ‘MPa/m^{1.5}’.

‘E_{abs}’, which is the absorption energy in Eq. 2-1, is defined by the following Eq. (A).

$$Absorption energy ( {E}_{abs} ) = {σ}^{2} * ( 1 - v ) / E ( MPa / {m}^{2} ) \qquad ( Eq . A )$$

In Eq. A, ‘σ’ is surface strength, and is defined by the following Eq. (B).

$$Surface strength ( σ ) = ( E * α * {ρ}^{2} ) / ( 1 - v ) {( MPa / m )}^{2} \qquad ( Eq . B )$$

In Eq. B, ‘E’ is Young's modulus, ‘α’ is a thermal expansion coefficient, ‘ρ’ is a density, and ‘v’ is Poisson's ratio.

The elastic energy index of the glass article 100 is related to the resistance to lower bending damage from external impacts. The first elastic energy index has a higher value as the brittleness decreases and the absorption energy increases. For example, according to Eqs. A and B, the first elastic energy index of the glass article 100 has an increased value as the surface strength increases, the brittleness decreases, and the absorption energy increases.

As described above, the glass article 100 can be manufactured by performing a quenching process and a chemical strengthening process during the manufacturing processes that uses the glass composition. The glass article 100 subjected to only a quenching process has physical properties that differ from those of the glass article 100 subjected to both a quenching process and a chemical strengthening process. In an embodiment, the first elastic energy index of the glass article 100 manufactured by performing a quenching process is 0.9*10⁵ MPa/m^{1.5} or more. In an embodiment, the first elastic energy index of the glass article 100 manufactured by performing the quenching process and the chemical strengthening process is 0.8*10⁵ MPa/m^{1.5} or more.

In accordance with an embodiment, other factors of the glass article 100 can be defined that are consistent with the pen drop test result in relation to the first elastic energy index. The second elastic energy index and the third elastic energy index of the glass article 100 are defined by the following Eqs. 2-2 and 2-3, respectively.

$$Second elastic energy index ( {E}_{elas 2} ) = {G}_{IC} * {( 1 / B )}^{6} * {{E}_{abs} ( kJ / {m}^{2} )}^{2} \qquad ( Eq . 2 - 2 )$$

$$Third elastic energy index ( {E}_{elas 3} ) = {G}_{IC} * ( 1 / B ) * {E}_{abs} ( {MPa}^{2} / {m}^{0.5} ) \qquad ( Eq . 2 - 3 )$$

In Eqs. 2-2 and 2-3, ‘G_{IC}’ is a facture energy index according to Eq. 1. The second elastic energy index and the third elastic energy index of Eqs. 2-2 and 2-3 include the correlation with the facture energy index G_{IC} of Eq. 1 in the first elastic energy index. The second elastic energy index Eₑₗₐₛ₂ and third elastic energy index Eₑₗₐₛ₃ are consistent with the pen drop test of the glass article 100 in the first elastic energy index Eₑₗₐₛ₁.

In an embodiment, the second elastic energy index of the glass article 100 manufactured by performing a quenching process is 0.12*10⁻⁴ (kJ/m²)² or more, and the third elastic energy index thereof is 2.3 MPa²/m^{0.5} or more. In an embodiment, the second elastic energy index of the glass article 100 manufactured by performing a quenching process and a chemical strengthening process is 0.1*10⁻⁴ (kJ/m²)² or more, and the third elastic energy index thereof is 2.1 MPa²/m^{0.5} or more.

In accordance with an embodiment, the glass article 100 has a first free volume index defined by the following Eq. 3-1.

$$First free volume index ( {V}_{t 1} ) = 1 / {T}_{g} ( {K}^{- 1} ) \qquad ( Eq . 3 - 1 )$$

In Eq. 3-1, ‘T_{g}’ is a glass transition temperature. The unit of the first free volume index Vₜ₁ of Eq. 3-1 may be ‘K⁻¹’.

The free volume index of the glass article 100 is related to the molecular vibration and the molecular structure of the glass article 100 for external impacts. The first free volume index Vₜ₁, which is related to the molecular structure of the glass article 100, has a value that decreases as the glass transition temperature increases. When the glass article 100 has a lot of space between molecules due to its molecular structure, for example, when the free volume is large, the molecular structure is not changed by external impacts and the glass article 100 has excellent breakage resistance against external impacts. However, this relationship involves a trade-off with a bonding strength and density of the glass article 100. In an embodiment, the first free volume index Vₜ₁ of the glass article 100 manufactured by performing a quenching process, and that of the glass article 100 manufactured by performing a quenching process and a chemical strengthening process is 0.001K⁻¹ or more.

In accordance with an embodiment, other factors of the glass article 100 that are consistent with the pen drop test result in relation to the first free volume index can be further defined. A second free volume index and a third free volume index of the glass article 100 may be defined by the following Eqs. 3-2 and 3-3, respectively.

$$Second free volume index ( {V}_{t 2} ) = {G}_{IC} * {( 1 / B )}^{6} * {E}_{abs} * ( 1 / {T}_{g} ) ( {( kJ / {m}^{2} )}^{2} / K ) \qquad ( Eq . 3 - 2 )$$

$$Third free volume index ( {V}_{t 3} ) = {G}_{IC} * ( 1 / B ) * {E}_{abs} * σ * ( 1 / {( {T}_{g} )}^{3} ) ( {MPa}^{4} / ( {m}^{2.5} * {K}^{3} ) ) \qquad ( Eq . 3 - 3 )$$

In Eqs. 3-2 and 3-3, ‘T_{g}’ is a glass transition temperature, ‘G_{IC}’ is a fracture energy index, ‘B’ is brittleness, ‘E_{abs}’ is absorption energy, and ‘σ’ is surface strength. The unit of the second free volume index Vₜ₂ of Eq. 3-2 is (kJ/m²)²/K, and the unit of the third free volume index Vₜ₃ of Eq. 3-3 is MPa⁴/(m^{2.5}*K³).

The second free volume index and the third free volume index of Eqs. 3-2 and 3-3 are correlated with the second elastic energy index and the third elastic energy index of Eqs. 2-2 and 2-3 in the first free volume index. Each of the second and third free volume indices Vₜ₂ and Vₜ₃ are consistent with the pen drop test of the glass article 100 in the first free volume index Vₜ₁. In an embodiment, the second free volume index Vₜ₂ of the glass article 100 manufactured by performing a quenching process is 10.0*10⁻⁸ (kJ/m²)²/K or more, the third free volume index Vₜ₃ thereof is 9.0*10⁻¹⁴ MPa⁴/(m^{2.5}*K³) or more. In an embodiment, the second free volume index V^{t2} of the glass article 100 manufactured by performing a quenching process and a chemical strengthening process is 7.0*10⁻⁸ (kJ/m²)²/K or more, and the third free volume index Vₜ₃ thereof is 6.0*10⁻¹⁴ MPa⁴/(m^{2.5}*K³).

Eqs. 1, 2-1 to 2-3, and 3-1 to 3-3 described above are related to the fracture energy, the elastic energy, and the free volume of the glass article 100, respectively. However, the ‘fracture energy index’, ‘elastic energy index’, and ‘free volume index’ of the glass article 100 in the disclosure may be defined by the above-described equations, and might not be equations that are completely equivalent to ‘fracture energy’, ‘elastic energy’, and ‘free volume’ that are commonly used in the technical field of the disclosure. The ‘fracture energy index’, ‘elastic energy index’, and ‘free volume index’ defined in the above equations may be defined by partially modified equations that are consistent with the pen drop test of the impact resistance characteristics of the glass article 100.

The glass article 100 according to an embodiment has a thickness of 100 μm or less, for example, 20 μm to 100 μm, or about 30 μm, and the fracture energy index, the elastic energy indices, and the free volume indices according to Eqs. 1, 2-1 to 2-3, and 3-1 to 3-3 satisfy values within the above-described ranges.

The glass article 100 is thin and foldable, and thus requires a high level of impact resistance characteristics. As described above, each of the measurable physical properties of the glass article 100 might not be consistent with the pen drop test result and the impact resistance characteristics of the glass article 100. For example, even if a specific physical property of the glass article 100 has a high value, the glass article 100 might not necessarily have excellent impact resistance characteristics. However, in accordance with an embodiment, the factors defined by Eqs. 1, 2-1 to 2-3, and 3-1 to 3-3 include the measurable physical properties of the glass article 100 that are consistent with the pen drop test result. Accordingly, a degree of impact resistance characteristics of the glass article 100 can be measured by the quantified factors of the glass article 100.

Further, the glass article 100 according to an embodiment has characteristics suitable for a cover window of the foldable display device 500. The glass article 100 has the above-described impact resistance characteristics and a small thickness, and satisfies transparency, content of foreign substances or cracks in a unit area, and light transmittance that are sufficient for the glass article 100 to be incorporated into the display device 500. The glass article 100 has the impact resistance characteristics because the above-described brittleness indices satisfy certain values, and has physical properties or characteristics required for a cover window of the display device 500 to provide a clear screen to a user.

In accordance with an embodiment, the glass article 100 has a stretch index β_{KWW} within a range of 0.95 to 1.00. The glass article 100 is suitable for use as the cover window of the foldable display device because it has excellent impact resistance characteristics while satisfying the above-described brittleness indices and has a high stretch index. The ‘stretch index’ is a physical property related to a strength factor, a Vogel temperature, and a glass transition temperature and indicates mobility and activity of atoms in the glass structure, and verifies the structural flow of the glass network structure. Since the glass article 100 has a high stretch index, it has excellent structural flow and flexible product characteristics.

Further, as described above, the glass article 100 includes various metal oxides, such as one or more of Na₂O, Li₂O, CaO or MgO, or ZrO₂, in addition to SiO₂ and Al₂O₃. The physical properties of the glass article 100 vary depending on a ratio between the content of the metal oxides in the glass article 100, and the content of Al₂O₃. In accordance with an embodiment, in the glass article 100, fluxes that are defined as a ratio (R¹₂O/R²O) of the content of a monovalent metal oxide R¹₂O, where ‘R¹’ is a monovalent metal element, to the content of a divalent metal oxide R²O, where ‘R²’ is a divalent metal element, in the metal oxide are within a range of 5 to 10, and an R-Ratio that is defined as a ratio (Al₂O₃/(R¹₂O+R²O)) of the content of Al₂O₃ to the total content (R¹₂O+R²O) of the metal oxide is within a range of 0.2 to 0.6. In the above formulas, ‘R₁’ and ‘R²’ are monovalent or divalent metal elements, and examples of ‘R¹₂O’ and ‘R²O’ that may be included in the glass article 100 include Na₂O, Li₂O, K₂O, CaO, MgO, etc. The glass article 100 has the above-described brittleness indices having certain values, a high stretch index, and the fluxes and the R-Ratio have values within the above-described ranges, and thus have excellent impact resistance characteristics and flexibility.

Hereinafter, results of the pen drop test performed on various glass articles 100 and the consistency evaluation between the above-described factors will be described.

### EXAMPLES

### Preparation Example 1: Preparation of Glass Article Specimens

A plurality of glass substrates having various compositions were prepared and divided into SAMPLE #1 to #21 and, then, a glass article preparation process was performed for each SAMPLE by the above-described method. The glass article specimen for each SAMPLE was prepared to have a thickness of 50 μm.

SAMPLEs of the glass article specimens were prepared by the following process.

The glass article specimen was molded into a glass block by weighing 500 g of PtRh10% crucible for each SAMPLE, increasing a temperature form 1500° C. to 1650° C. at a rate of 10K/min, maintaining the temperature for 3 to 6 hours, and rapidly cooling it in a carbon mold to 600° C.

To remove the residual stress of the prepared glass block, annealing was performed at a temperature higher than the glass transition temperature for each SAMPLE by 30° C. for 1 to 6 hours and, then, the glass block was cooled to 400° C. at a rate of 1 K/min and then cooled to room temperature, thereby obtaining a glass block with a thickness of 10 mm.

To perform the pen drop test on the prepared glass blocks, the glass blocks were cut into a thickness of 270 μm using diamond wire saw equipment, and then polished on both sides until the thickness became 50 μm.

The specimen processed to 50 μm for each SAMPLE was chemically strengthened using KNO₃ molten salt. The surface compressive stress (CS) was controlled to be within a range of 700 MPa to 800 MPa, and the depth of layer (DoL) was controlled to be within a range of 15% to 20% compared to the glass thickness. However, some SAMPLEs were subjected to the pen drop test without being subjected to the chemical strengthening process.

To compare the factors defined by the above equations with the actual pen drop test results of the glass article specimen, the structural flow of the glass article specimens was checked by a theoretical viscosity calculation, and the impact resistance major factor was checked by a physical property analysis. First, the viscosity of glass was checked by the Vogel-Fulcher-Tammann (VFT) equation, and the following Eq. (1) relates the viscosity and temperature of the glass.

$$log η = {A}_{VFT} + \frac{{B}_{VFT}}{T - {T}_{0}} \qquad ( 1 )$$

where η is viscosity, A_{VFT} is high temperature limit viscosity, T₀ is a Vogel temperature, and B_{VFT} is viscosity at T₀.

To check the flow of the glass structure based on the Vogel temperature, the following Eq. (2) was derived based on the Kohlrauscb-Williams-Watts (KWW) formula.

$${β}_{KWW} = 1 - \sqrt{\frac{{( {T}_{0} - {T}_{g} )}^{2}}{D}} \qquad ( 2 )$$

Here, β_{KWW} is a stretch index, D is a strength factor (=B_{VFT}/T₀), T₀ is a Vogel temperature, and T_{g} is a glass transition temperature. The Vogel temperature T₀ is an ideal glass transition temperature T_{g}, and generally refers to the point where the free volume required for relaxation of the glass network structure is theoretically zero without the influence of manufacturing conditions such as a cooling rate, a capacity, and defects of glass specimens. Therefore, the viscosity at which the glass network structure is formed can be determined by the Vogel temperature comparison. Further, the stretch index β_{KWW} calculated by T₀ indicates mobility and activity of atoms in the glass structure, and verifies the structural flow of the glass network structure.

Next, the physical properties of the glass article specimen for each SAMPLE were measured and are shown in the following Table 1 together with the Vogel temperature T₀ and the stretch index β_{KWW}. The measured physical properties of the glass article specimen include a thermal expansion coefficient CTE, a glass transition temperature T_{g}, a density ρ, a Young's modulus E, a Poisson's ratio v, a hardness Hv, a fracture toughness K_{IC}, and a brittleness B.

The glass transition temperature T_{g} was checked by preparing 5 g for each glass SAMPLE using differential thermal analysis (DTA) equipment and increasing a temperature to the glass transition temperature range at a rate of 10 K/min. The thermal expansion coefficient of glass was checked by preparing a specimen with a size of 10×10×13 mm³ for each composition using thermo mechanical analyzer (TMA) equipment and increasing the temperature at a rate of 10 K/min to the glass transition temperature range.

The Poisson's ratio was checked by manufacturing a specimen with a size of 10×20×3 mm³ for each composition and checking the stress and strain of the specimen using an elastic modulus tester.

The hardness H_{V} and the fracture toughness K_{IC} were calculated by the following Eqs. (3) and (4) by applying a load of 4.9 N for 30 seconds with Vickers hardness tester equipment using a diamond tip with a size of 19 μm.

$${H}_{V} = 1.854 \cdot \frac{F}{{a}^{2}} \qquad ( 3 )$$

where, H_{V} indicates Vickers hardness, F indicates a load, and a indicates an indentation length.

$$\frac{{K}_{IC} \cdot ϕ}{{H}_{V} \cdot {a}^{\frac{1}{2}}} = 0.15 \cdot K \cdot {( \frac{c}{a} )}^{- \frac{3}{2}} \qquad ( 4 )$$

where, K_{IC} indicates fracture toughness, ϕ indicates a constraint index (ϕ≈3), H_{V} indicates Vickers hardness, K indicates a constant (=3.2), c indicates a crack length, and a indicates an indentation length.

Brittleness (B) was calculated by the following Eq. (5) by applying a load of 4.9 N for 30 seconds using Vickers hardness tester equipment.

$$B = γ {P}^{- 1 / 4} {\frac{C}{a}}^{3 / 2} \qquad ( 5 )$$

where B is brittleness, γ is a constant (2.39N^{1/4}/μm^{1/2}), P is an indentation load, a is an indentation length, and C is a crack length.

The crack generation load was measured using Vickers hardness tester equipment.

TABLE 1

| | CTE | T_{g} | ρ | E | v | Hᵥ | K_{IC} | B |
|---|---|---|---|---|---|---|---|---|
| Sample group Unit | 10⁻⁷/K | K | g/cm³ | MPa | — | MPa | MPa*m^{0.5} | μm^{-0.5} |
| SAMPLE#1 | 84 | 859.1 | 2.464 | 85000 | 0.213 | 6678.3 | 1.27 | 5.26 |
| SAMPLE#2 | 84 | 862.1 | 2.458 | 80000 | 0.202 | 6697.9 | 1.38 | 4.85 |
| SAMPLE#3 | 74 | 888.1 | 2.446 | 79000 | 0.202 | 6531.2 | 1.29 | 5.06 |
| SAMPLE#4 | 73.2 | 816.1 | 2.443 | 105000 | 0.348 | 5854.6 | 1.09 | 5.37 |
| SAMPLE#5 | 80 | 963.1 | 2.442 | 80000 | 0.202 | 6786.2 | 1.28 | 5.3 |
| SAMPLE#6 | 90 | 938.1 | 2.466 | 65000 | 0.242 | 5148.5 | 0.901 | 5.71 |
| SAMPLE#7 | 91 | 791.1 | 2.48 | 73000 | 0.23 | 5285.8 | 0.78 | 6.78 |
| SAMPLE#8 | 91.2 | 827.1 | 2.434 | 66000 | 0.197 | 4785.6 | 0.896 | 5.34 |
| SAMPLE#9 | 85.9 | 859.1 | 2.555 | 67000 | 0.242 | 5295.6 | 0.781 | 6.78 |
| SAMPLE#10 | 89 | 880.1 | 2.46 | 72000 | 0.22 | 5393.7 | 0.87 | 6.2 |
| SAMPLE#11 | 85.6 | 838.1 | 2.503 | 63000 | 0.237 | 5060.2 | 0.787 | 6.43 |
| SAMPLE#12 | 79.9 | 860.1 | 2.5 | 74000 | 0.13 | 5266.2 | 0.815 | 6.46 |
| SAMPLE#13 | 76 | 1003.1 | 2.444 | 78000 | 0.219 | 6501.8 | 1.29 | 5.04 |
| SAMPLE#14 | 77.1 | 959.1 | 2.63 | 64000 | 0.277 | 4658.2 | 0.914 | 5.1 |
| SAMPLE#15 | 82 | 860.1 | 2.473 | 82000 | 0.202 | 7011.8 | 1.02 | 6.87 |
| SAMPLE#16 | 84 | 1054.1 | 2.454 | 71000 | 0.197 | 5079.8 | 0.873 | 5.82 |
| SAMPLE#17 | 45 | 1040.1 | 2.555 | 86000 | 0.254 | 6492 | 1.082 | 6 |
| SAMPLE#18 | 35.2 | 1045.1 | 2.56 | 85000 | 0.243 | 7100 | 0.919 | 7.73 |
| SAMPLE#19 | 30.4 | 1028.1 | 2.512 | 92000 | 0.254 | 7433.4 | 1.067 | 6.97 |
| SAMPLE#20 | 85 | 932.1 | 2.428 | 66000 | 0.242 | 5060.2 | 0.772 | 6.55 |
| SAMPLE#21 | 61.9 | 952.1 | 2.458 | 72000 | 0.228 | 6648.9 | 0.928 | 7.16 |

In the table, ‘CTE’ is a thermal expansion coefficient, ‘T_{g}’ is a glass transition temperature, ‘ρ’ is a density, ‘E’ is Young's modulus, ‘v’ is Poisson's ratio, ‘Hv’ is hardness, and ‘KIC’ is fracture toughness, and ‘B’ is brittleness.

### Test Example 1: Impact Resistance Evaluation—Pen Drop (Pen Diameter 0.7 mm) Evaluation

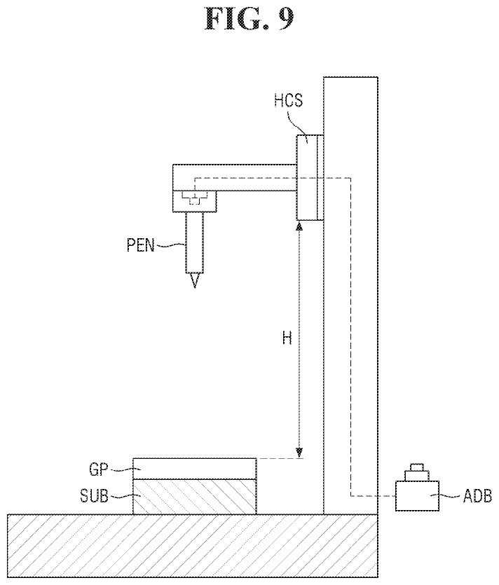

A pen drop test (PDT) was performed as shown in FIG. 9 using the glass article specimens prepared in Preparation Example 1. The pen drop test was performed using glass article specimens subjected to both a quenching process and a chemical strengthening process.

FIG. 9 illustrates a pen drop test method of a glass article specimen according to an embodiment.

Referring to FIG. 9, in an embodiment, a glass article sample GP that has a thickness of 50 μm was prepared and bonded to a polyethylene film substrate SUB that has a thickness of 250 μm. After the glass article sample GP and the substrate SUB are bonded and cured for more than 30 minutes, the pen drop test was performed. The pen drop test was performed by dropping a pen PEN having a ball diameter of 0.7 mm and a weight of 1.12 g at a temperature of 20° C. to 22° C. and a humidity of 30% using an automatic dropping device (ADB) until breakage occurred in the glass article sample GP. A drop height H was increased at an interval of 0.5 cm using a drop height control device HCS, and the glass article sample GP was observed after one impact by a microscope to check whether cracks or breakage had occurred. The drop height H was defined as the vertical distance from the glass article sample GP to the drop height control device HCS.

The pen drop test was performed 30 times on three or more same glass article samples GP, and the average value was measured and is shown in the following Table 2. Further, the physical properties measured in Preparation Example 1, the elastic energy indices and the free volume indices defined in Eqs. 2-1 to 2-3 and 3-1 to 3-3, and the stretch indices were calculated and are shown in the following Table 2. The fracture energy index, the elastic energy index, and the free volume index shown in the following Table 2 are values of glass article samples subjected to both the quenching process and the chemical strengthening process.

TABLE 2

| | | | | | | Eq. 3-2 | Eq. 3-3 | |
|---|---|---|---|---|---|---|---|---|
| | | Eq. 2-1 | Eq. 2-2 | Eq. 2-3 | | (Vₜ₂) | (Vₜ₃) | Stretch |
| | PDT | (Eₑₗₐₛ₁) | (Eₑₗₐₛ₂) | (Eₑₗₐₛ₃) | | (kJ/m²)²/ | MPa⁴/ | index |
| Sample group | (H) | MPa/m^{1.5} | (kJ/m²)² | MPa/ | Eq. 3-1 | K | m^{2.5}K³ | (β_{KWW}) |
| Unit | (cm) | (*10⁵) | (10⁻⁵) | m^{0.5} | (Vₜ₁)/K | (10⁻⁷) | (10⁻¹⁴) | — |
| SAMPLE#1 | 6.68 | 1.31 | 5.88 | 2.365 | 0.0016 | 0.685 | 8.41 | 0.993 |
| SAMPLE#2 | 6.57 | 1.11 | 9.41 | 2.533 | 0.0016 | 1.09 | 9.65 | 0.994 |
| SAMPLE#3 | 5.98 | 0.59 | 3.60 | 1.199 | 0.00113 | 0.41 | 5 | 0.949 |
| SAMPLE#4 | 5.92 | 2.28 | 5.08 | 2.27 | 0.00123 | 0.62 | 7 | 0.924 |
| SAMPLE#5 | 3.98 | 0.79 | 3.72 | 1.558 | 0.00104 | 0.39 | 5 | 0.937 |
| SAMPLE#6 | 3.96 | 0.8 | 1.53 | 0.938 | 0.00107 | 0.16 | 3 | 0.760 |
| SAMPLE#7 | 3.23 | 0.99 | 0.55 | 0.785 | 0.00126 | 0.07 | 4 | — |
| SAMPLE#8 | 3.15 | 0.71 | 1.91 | 0.835 | 0.00121 | 0.23 | 4 | 0.901 |
| SAMPLE#9 | 2.63 | 0.81 | 0.49 | 0.695 | 0.00116 | 0.06 | 3 | 0.877 |
| SAMPLE#10 | 2.5 | 0.86 | 0.93 | 0.86 | 0.00114 | 0.11 | 3 | 0.803 |
| SAMPLE#11 | 2.5 | 0.58 | 0.49 | 0.541 | 0.00119 | 0.06 | 3 | 0.889 |
| SAMPLE#12 | 2.17 | 0.48 | 0.37 | 0.421 | 0.00116 | 0.04 | 2 | 0.876 |
| SAMPLE#13 | 2.16 | 0.68 | 4.22 | 1.374 | 0.001 | 0.42 | 4 | 0.959 |
| SAMPLE#14 | 2.02 | 0.09 | 3.1 | 1.069 | 0.00104 | 0.32 | 3 | 0.76 |
| SAMPLE#15 | 2.02 | 0.8 | 0.63 | 0.979 | 0.00116 | 0.074 | 4 | 0.929 |
| SAMPLE#16 | 2 | 0.62 | 0.97 | 0.647 | 0.00095 | 0.09 | 2 | 0.75 |
| SAMPLE#17 | 1.91 | 0.15 | 0.25 | 0.195 | 0.00096 | 0.02 | 1 | 0.925 |
| SAMPLE#18 | 1.5 | 0.04 | 0.01 | 0.039 | 0.00096 | 0.001 | 0.9 | 0.966 |
| SAMPLE#19 | 1.5 | 0.03 | 0.02 | 0.034 | 0.00097 | 0.002 | 0.9 | 0.876 |
| SAMPLE#20 | 1.2 | 0.51 | 0.36 | 0.435 | 0.00107 | 0.04 | 2 | 0.531 |
| SAMPLE#21 | 0.83 | 0.18 | 0.11 | 0.202 | 0.00105 | 0.01 | 1 | 0.801 |

In Table 2, the glass article SAMPLEs were ranked in the order of pen drop (PDT) test results. In the pen drop test, SAMPLE #1 has excellent impact resistance characteristics because cracks were generated at the highest position, and SAMPLE #21 has poor impact resistance characteristics because cracks were generated at the lowest position.

Referring to Table 2, the pen drop test results and the values of Eqs. 2-1 to 2-3 and 3-1 to 3-3 show substantially the same tendency. SAMPLEs that have small values of Eqs. 2-1 to 2-3 and 3-1 to 3-3 substantially have poor pen drop test results. For example, if the fracture energy index, the elastic energy index, and the free volume index described above have small values, the impact resistance characteristics are poor. SAMPLEs having large values of Eqs. 2-1 to 2-3 and 3-1 to 3-3 substantially have excellent pen drop test results. For example, if the fracture energy index, the elastic energy index, and the free volume index have large values, the impact resistance characteristics are excellent.

### Preparation Example 2: Evaluation of Physical Properties According to Quenching Process in Manufacturing Glass Articles

In Preparation Example 1, a glass article specimen for only physical property evaluation was prepared, molded into a bock sample, and tested. The glass article 100 that can be incorporated into an actual display device, such as a cover window of a foldable display device, can be manufactured by a process that differs from a manufacturing process of Preparation Example 1. The glass article 100 can be manufactured by performing a quenching process of the glass composition using a roll rather than a carbon mold during the manufacturing process of Preparation Example 1. The glass article 100 of this Preparation Example is different in that it was manufactured by performing a quenching process using the glass sheet rather than a glass block and a chemical strengthening process performed in Preparation Example 1 was not performed.

The elastic energy indices and the free volume indices of the glass article 100 manufactured by the above-described manufacturing process and which were defined in Eqs. 2-1 to 2-3 and 3-1 to 3-3, were calculated and are shown in the following Table 3.

TABLE 3

| | | | | | Eq. 3-2 | Eq. 3-3 |
|---|---|---|---|---|---|---|
| | Eq. 2-1 | Eq. 2-2 | Eq. 2-3 | | (Vₜ₂) | (Vₜ₃) |
| | (Eₑₗₐₛ₁) | (Eₑₗₐₛ₂) | (Eₑₗₐₛ₃) | | (kJ/m²)²/ | MPa⁴/ |
| Sample group | MPa/m^{1.5} | (kJ/m²)² | MPa/ | Eq. 3-1 | K | m^{2.5}K³ |
| Unit | (*10⁵) | (10⁻⁵) | m^{0.5} | (Vₜ₁)/K | (10⁻⁷) | (10⁻¹⁴) |
| SAMPLE#1 | 1.20 | 12.9 | 2.641 | 0.0017 | 1.5 | 10.1 |
| SAMPLE#2 | 1.02 | 21.0 | 2.828 | 0.0016 | 2.4 | 11.6 |
| SAMPLE#3 | 0.54 | 7.92 | 1.338 | 0.00113 | 0.89 | 6 |
| SAMPLE#4 | 2.12 | 11.23 | 2.55 | 0.00123 | 1.4 | 9 |
| SAMPLE#5 | 0.73 | 8.18 | 1.739 | 0.00104 | 0.85 | 5 |
| SAMPLE#6 | 0.73 | 3.39 | 1.049 | 0.00107 | 0.36 | 4 |
| SAMPLE#7 | 0.92 | 1.21 | 0.877 | 0.00127 | 0.15 | 4 |
| SAMPLE#8 | 0.66 | 4.22 | 0.931 | 0.00121 | 0.51 | 5 |
| SAMPLE#9 | 0.75 | 1.08 | 0.777 | 0.00117 | 0.12 | 3 |
| SAMPLE#10 | 0.96 | 2.07 | 0.79 | 0.00114 | 0.24 | 4 |
| SAMPLE#11 | 0.54 | 1.08 | 0.605 | 0.00120 | 0.13 | 3 |
| SAMPLE#12 | 0.44 | 0.82 | 0.469 | 0.00117 | 0.10 | 2 |
| SAMPLE#13 | 0.62 | 9.29 | 1.534 | 0.001 | 0.93 | 4 |
| SAMPLE#14 | 0.08 | 6.9 | 1.197 | 0.00105 | 0.72 | 4 |
| SAMPLE#15 | 0.74 | 1.40 | 1.092 | 0.00117 | 0.16 | 4 |
| SAMPLE#16 | 0.58 | 2.13 | 0.722 | 0.00095 | 0.20 | 2 |
| SAMPLE#17 | 0.14 | 0.55 | 0.218 | 0.00096 | 0.05 | 1 |
| SAMPLE#18 | 0.04 | 0.03 | 0.044 | 0.00096 | 0.003 | 0.9 |
| SAMPLE#19 | 0.03 | 0.05 | 0.038 | 0.00098 | 0.003 | 0.9 |
| SAMPLE#20 | 0.47 | 0.79 | 0.486 | 0.00108 | 0.09 | 2 |
| SAMPLE#21 | 0.16 | 0.23 | 0.226 | 0.00105 | 0.03 | 1 |

Referring to Table 3, the glass article 100 subjected to only the quenching process in the manufacturing process of the glass article 100 differs from the glass article specimens of Table 2 in the values of Eqs. 2-1 to 2-3 and 3-1 to 3-3. However, in the glass article 100 of this Preparation Example, the elastic energy index and the free volume index of SAMPLE #1 and SAMPLE #2 have excellent pen drop test results that are larger than those of other SAMPLEs. For example, the glass article 100 manufactured in this Preparation Example is more consistent with the values of Eqs. 2-1 to 2-3 and 3-1 to 3-3 and the pen drop test results of Table 2. For example, even when the glass article 100 manufactured by performing a quenching process, the pen drop characteristics are excellent based on the values of Eqs. 2-1 to 2-3 and 3-1 to 3-3. Accordingly, in the case of evaluating the physical properties or the pen drop characteristics of the glass article 100, the impact resistance characteristics of the glass article 100 can be determined based on the physical properties of the glass article 100 itself and the values of Eqs. 2-1 to 2-3 and 3-1 to 3-3 without preparing the same glass composition as the glass article 100, manufacturing a separate block specimen, and evaluating the physical properties thereof.

The following Table 4 shows changes in the physical properties of the glass article specimens of Preparation Example 1 and the glass article 100 of Preparation Example 2.

TABLE 4

| Physical property | Change amount |
|---|---|
| CTE | 2.0(−) |
| Tg | 0.3(−) |
| ρ | 0.3(−) |
| E | 4.0(−) |
| v | 1.0(+) |
| Hᵥ | 5.7(−) |
| K_{IC} | 8.0(+) |
| B | 15.6(−) |

In Table 4, the ‘change amount’ refers to a degree of change as compared to a reference sample, rather than an absolute numerical change amount. Referring to Table 4, when performing a quenching process during the manufacturing process of the glass article 100, various physical properties of the glass article 100, such as the thermal expansion coefficient CTE, the glass transition temperature T_{g}, the density ρ, the Young's modulus E, the Poisson's ratio v, the hardness Hᵥ, the fracture toughness K_{IC}, and the brittleness B, change. Although it is not necessary for the physical properties to change with a certain trend, the glass article 100 subjected to a quenching process has physical properties in which the values according to Eqs. 2-1 to 2-3 and 3-1 to 3-3 are consistent with the pen drop test results. The glass article 100 according to one embodiment may have excellent pen drop characteristics because the values according to Eqs. 2-1 to 2-3 and 3-1 to 3-3 satisfy a specific range, and may have impact resistance characteristics suitable for application to a foldable display product.

### Preparation Example 3: Evaluation of Physical Properties According to Quenching Process and Chemical Strengthening Process

Unlike Preparation Example 2, the glass article 100 was prepared that was subjected to a quenching process and the same chemical strengthening process as in Preparation Example 1, and the elastic energy indices and the free volume indices defined in Eqs. 2-1 to 2-3 and 3-1 to 3-3 were calculated and are shown in the following Table 5.

TABLE 5

| | | | | | Eq. 3-2 | Eq. 3-3 |
|---|---|---|---|---|---|---|
| | Eq. 2-1 | Eq. 2-2 | Eq. 2-3 | | (Vₜ₂) | (Vₜ₃) |
| | (Eₑₗₐₛ₁) | (Eₑₗₐₛ₂) | (Eₑₗₐₛ₃) | | (kJ/m²)²/ | MPa⁴/ |
| Sample group | MPa/m^{1.5} | (kJ/m²)² | MPa/ | Eq. 3-1 | K | m^{2.5}K³ |
| Unit | (*10⁵) | (10⁻⁵) | m^{0.5} | (Vₜ₁)/K | (10⁻⁷) | (10⁻¹⁴) |
| SAMPLE#1 | 1.14 | 7.9 | 2.491 | 0.0017 | 0.92 | 9.4 |
| SAMPLE#2 | 0.97 | 10.3 | 2.668 | 0.0016 | 1.5 | 11 |
| SAMPLE#3 | 0.52 | 4.81 | 1.262 | 0.00113 | 0.54 | 5 |
| SAMPLE#4 | 2.00 | 6.78 | 2.39 | 0.00123 | 0.83 | 8 |
| SAMPLE#5 | 0.69 | 4.97 | 1.641 | 0.00104 | 0.52 | 5 |
| SAMPLE#6 | 0.7 | 2.06 | 0.988 | 0.00107 | 0.22 | 3 |
| SAMPLE#7 | 0.87 | 0.72 | 0.826 | 0.00127 | 0.09 | 4 |
| SAMPLE#8 | 0.63 | 2.56 | 0.879 | 0.00121 | 0.31 | 5 |
| SAMPLE#9 | 0.71 | 0.65 | 0.732 | 0.00117 | 0.08 | 3 |
| SAMPLE#10 | 0.75 | 1.25 | 0.906 | 0.00114 | 0.14 | 4 |
| SAMPLE#11 | 0.51 | 0.66 | 0.570 | 0.00120 | 0.08 | 3 |
| SAMPLE#12 | 0.42 | 0.49 | 0.443 | 0.00117 | 0.06 | 2 |
| SAMPLE#13 | 0.59 | 5.63 | 1.447 | 0.001 | 0.56 | 4 |
| SAMPLE#14 | 0.08 | 4.14 | 1.126 | 0.00105 | 0.43 | 4 |
| SAMPLE#15 | 0.7 | 0.85 | 1.031 | 0.00117 | 0.099 | 4 |
| SAMPLE#16 | 0.55 | 1.29 | 0.681 | 0.00095 | 0.12 | 2 |
| SAMPLE#17 | 0.13 | 0.33 | 0.205 | 0.00096 | 0.03 | 1 |
| SAMPLE#18 | 0.03 | 0.02 | 0.041 | 0.00096 | 0.002 | 0.9 |
| SAMPLE#19 | 0.03 | 0.03 | 0.036 | 0.00098 | 0.0027 | 0.9 |
| SAMPLE#20 | 0.45 | 0.48 | 0.438 | 0.00108 | 0.052 | 2 |
| SAMPLE#21 | 0.16 | 0.14 | 0.213 | 0.00105 | 0.015 | 1 |

Referring to Table 5, the glass article 100 subjected to a quenching process and a chemical strengthening process in the manufacturing process of the glass article 100 differs from the glass article specimens of Tables 2 and 3 in the values of Eqs. 2-1 to 2-3 and 3-1 to 3-3. However, in the glass article 100 of this Preparation Example, the elastic energy indices and the free volume indices of SAMPLE #1 and SAMPLE #2 have excellent pen drop test results that are larger than those of other SAMPLEs. For example, the glass article 100 manufactured in this Preparation Example are more consistent with the values of Eqs. 2-1 to 2-3 and 3-1 to 3-3 and the pen drop test results of Table 2. For example, in the case of the glass article 100 manufactured by performing quenching, the pen drop characteristics are excellent based on the values of Eqs. 2-1 to 2-3 and 3-1 to 3-3.

The following Table 6 shows changes in the physical properties of the glass article specimens of Preparation Example 1 and the glass article 100 of Preparation Example 3.

TABLE 6

| Physical property | Change amount |
|---|---|
| CTE | 1.6(−) |
| Tg | 0.3(−) |
| ρ | 0.3(−) |
| E | 3.0(−) |
| v | — |
| Hᵥ | 3.0(−) |
| K_{IC} | 8.0(+) |
| B | 15.6(−) |

In Table 6, the ‘change amount’ indicates a degree of change as compared to a reference sample rather than an absolute numerical change amount. Referring to Table 6, when performing a quenching process and a chemical strengthening process during the manufacturing process of the glass article 100, various physical properties of the glass article 100, such as the thermal expansion coefficient CTE, the glass transition temperature T_{g}, the density ρ, the Young's modulus E, the Poisson's ratio v, the hardness Hᵥ, the fracture toughness K_{IC}, and the brittleness B, change. Although it is not necessary for the physical properties change with a certain trend, the glass article 100 subjected to a quenching process and a chemical strengthening process have physical properties in which the values according to Eqs. 2-1 to 2-3 and 3-1 to 3-3 are consistent with the pen drop test results. The glass article 100 according to an embodiment have excellent pen drop characteristics because the values according to Eqs. 2-1 to 2-3 and 3-1 to 3-3 satisfy a specific range, and have impact resistance characteristics suitable for use in a foldable display product.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

What is claimed is:

1. A glass article,
wherein a thickness ranges from 20 μm to 150 μm,
a first elastic energy index defined by a following Eq. 2-1 is equal to or greater than 0.8 MPa²/m^{0.5};
$$first elastic energy index ( {E}_{elas 1} ) = ( 1 / B ) * {E}_{abs} , \qquad ( Eq . 2 - 1 )$$
wherein ‘B’ is a brittleness, and ‘E_{abs}’ is an absorption energy defined by a following Eq. A:
$$absorption energy ( {E}_{abs} ) = {σ}^{2} * ( 1 - v ) / E , \qquad ( Eq . A )$$
wherein ‘σ’ is a surface strength and is defined by a following Eq. B:
$$surface strength ( σ ) = ( E * α * {ρ}^{2} ) / ( 1 - v ) , \qquad ( Eq . B )$$
wherein ‘E’ is Young's modulus, ‘α’ is a thermal expansion coefficient, ‘ρ’ is a density, and ‘v’ is Poisson's ratio, and
a stretch index (β_{KWW}) defined by a following Eq. 2 is equal to or greater than 0.95:
$${β}_{KWW} = 1 - \sqrt{\frac{{( {T}_{0} - {T}_{g} )}^{2}}{D}} , \qquad ( 2 )$$
wherein ‘D’ is a strength factor (=B_{VFT}/T₀), ‘T₀’ is a Vogel temperature, and ‘T_{g}’ is a glass transition temperature.

2. The glass article of claim 1, wherein the first elastic energy index is equal to or greater than 0.9 MPa²/m^{0.5}.

3. The glass article of claim 1,
wherein a second elastic energy index defined by a following Eq. 2-2 is equal to or greater than 0.1*10⁻⁴ (kJ/m²)²:
$$second elastic energy index ( {E}_{elas 2} ) = {G}_{IC} * {( 1 / B )}^{6} * {E}_{abs} , \qquad ( Eq . 2 - 2 )$$
wherein ‘G_{IC}’ is a facture energy index according to a following Eq. 1, ‘B’ is a brittleness, and ‘E_{abs}’ is an absorption energy:
$$fracture energy index ( {G}_{IC} ) = ( {{K}_{IC}}^{2} * ( 1 - {v}^{2} ) ) / E , \qquad ( Eq . 1 )$$
wherein ‘K_{IC}’ is a fracture toughness, ‘v’ is Poisson's ratio, and ‘E’ is Young's modulus.

4. The glass article of claim 3, wherein the second elastic energy index is equal to or greater than 0.12*10⁻⁴ (kJ/m²)².

5. The glass article of claim 3, wherein the facture energy index is equal to or greater than 150 kJ/m².

6. The glass article of claim 3,
wherein a third elastic energy index defined by a following Eq. 2-3 is equal to or greater than 2.1 MPa²/m^{0.5};
$$third elastic energy index ( {E}_{elas 3} ) = {G}_{IC} * ( 1 / B ) * {E}_{abs} \qquad ( Eq . 2 - 3 )$$
wherein ‘G_{IC}’ is the facture energy index, ‘B’ is a brittleness, and ‘E_{abs}’ is the absorption energy.

7. The glass article of claim 6, wherein the third elastic energy index is equal to or greater than 2.3 MPa²/m^{0.5}.

8. The glass article of claim 1, wherein a crack generation height in a pen drop test performed with a pen having a ball diameter of 0.7 mm and a weight of 1.12 g, is equal to or greater than 6 cm.

9. The glass article of claim 1, wherein the glass article contains SiO₂, Al₂O₃, and at least one metal oxide,
fluxes defined as a ratio of a content of a monovalent metal oxide to a content of a divalent metal oxide in the at least one metal oxide are within a range of 7.0 to 8.5, and
a ratio of a content of Al₂O₃ to a total content of the at least one metal oxide is within a range of 0.3 to 0.4.

10. A glass article,
wherein a thickness ranges from 20 μm to 150 μm,
a first free volume index defined by a following Eq. 3-1 is equal to or greater than 0.001K⁻¹;
$$first free volume index ( {V}_{t 1} ) = 1 / {T}_{g} , \qquad ( Eq . 3 - 1 )$$
wherein ‘T_{g}’ is a glass transition temperature, and
a stretch index (β_{KWW}) defined by a following Eq. 2 is equal to or greater than 0.95:
$${β}_{KWW} = 1 - \sqrt{\frac{{( {T}_{0} - {T}_{g} )}^{2}}{D}} , \qquad ( 2 )$$
wherein ‘D’ is a strength factor (=B_{VFT}/T₀), ‘T₀’ is a Vogel temperature, and ‘T_{g}’ is a glass transition temperature.

11. The glass article of claim 10,
wherein a second free volume index defined by a following Eq. 3-2 is equal to or greater than 7.0*10⁻⁸ (kJ/m²)²/K:
$$second free volume index ( {V}_{t 2} ) = {G}_{IC} * {( 1 / B )}^{6} * {E}_{abs} * ( 1 / {T}_{g} ) , \qquad ( Eq . 3 - 2 )$$
wherein ‘T_{g}’ is a glass transition temperature, ‘B’ is a brittleness, and ‘G_{IC}’ is a facture energy index defined by a following Eq. 1:
$$fractured energy index ( {G}_{IC} ) = ( {K}_{IC}^{2} * ( 1 - {v}^{2} ) ) / E , \qquad ( Eq . 1 )$$
wherein ‘K_{IC}’ is a fracture toughness, ‘v’ is Poisson's ratio, and ‘E’ is Young's modulus,
‘E_{abs}’ is an absorption energy and is defined by a following Eq. (A):
$$absorption energy ( {E}_{a b s} ) = {σ}^{2} * ( 1 - v ) / E \qquad ( A )$$
wherein ‘σ’ is a surface strength and is defined by a following Eq. B:
$$surface strength ( σ ) = ( E * α * {ρ}^{2} ) / ( 1 - v ) , \qquad ( Eq . B )$$
wherein ‘E’ is Young's modulus, ‘α’ is a thermal expansion coefficient, ‘ρ’ is a density, and ‘v’ is Poisson's ratio.

12. The glass article of claim 11, wherein the second free volume index is equal to or greater than 10.0*10⁻⁸ (kJ/m²)²/K.

13. The glass article of claim 12,
wherein a third free volume index defined by a following Eq. 3-3 is equal to or greater than 6.0*10⁻¹⁴ MPa⁴/(m^{2.5}*K³):
$$third free volume index ( {V}_{t 3} ) = {G}_{IC} * ( 1 / B ) * {E}_{abs} * σ * ( 1 / {( {T}_{g} )}^{3} ) , \qquad ( Eq . 3 - 3 )$$
wherein ‘T_{g}’ is a glass transition temperature, ‘G_{IC}’ is a facture energy index, ‘B’ is the brittleness, ‘E_{abs}’ is the absorption energy, and ‘σ’ is the surface strength.

14. The glass article of claim 13, wherein the third free volume index is equal to or greater than 9.0*10⁻¹⁴ MPa⁴/(m^{2.5}*K³).

15. The glass article of claim 10, wherein a crack generation height in a pen drop test performed with a pen having a ball diameter of 0.7 mm and a weight of 1.12 g is equal to or greater than 6 cm.

16. The glass article of claim 10, wherein the glass article contains SiO₂, Al₂O₃, and at least one metal oxide,
fluxes defined as a ratio of a content of a monovalent metal oxide to a content of a divalent metal oxide in the at least one metal oxide are within a range of 7.0 to 8.5, and
a ratio of a content of Al₂O₃ to a total content of the at least one metal oxide is within a range of 0.3 to 0.4.

17. A display device, comprising:
a display panel that includes a plurality of pixels;
a cover window disposed above the display panel; and
an optically transparent bonding layer disposed between the display panel and the cover window,
wherein the cover window comprises a glass article whose thickness ranges from 20 μm to 100 μm,
whose first elastic energy index defined by a following Eq. 2-1 is equal to or greater than 0.8 MPa²/m^{0.5};
$$first elastic energy index ( {E}_{e las 1} ) = ( 1 / B ) * {E}_{a b s} , \qquad ( Eq . 2 - 1 )$$
where ‘B’ is a brittleness, and ‘E_{abs}’ is an absorption energy and is defined by a following Eq. A:
$$absorption energy ( {E}_{a b s} ) = {σ}^{2} * ( 1 - v ) / E , \qquad ( A )$$
wherein ‘σ’ is a surface strength and is defined by a following Eq. B:
$$surface strength ( σ ) = ( E * α * {ρ}^{2} ) / ( 1 - v ) , \qquad ( Eq . B )$$
wherein ‘E’ is Young's modulus, ‘α’ is a thermal expansion coefficient, ‘ρ’ is a density, and ‘v’ is Poisson's ratio, and
whose first free volume index defined by a following Eq. 3-1 is equal to or greater than 0.001K⁻¹:
$$first free volume index ( {V}_{t 1} ) = 1 / {T}_{g} , \qquad ( Eq . 3 - 1 )$$
wherein ‘T_{g}’ is a glass transition temperature, and
whose stretch index (β_{KWW}) defined by a following Eq. 2 is equal to or greater than 0.95:
$${β}_{K W W} = 1 - \sqrt{\frac{{( {T}_{0} - {T}_{g} )}^{2}}{D}} , \qquad ( 2 )$$
wherein ‘D’ is a strength factor (=B_{VFT}/T₀), ‘T₀’ is a Vogel temperature, and ‘T_{g}’ is a glass transition temperature.

18. The display device of claim 17, wherein in the glass article,
a second elastic energy index defined by a following Eq. 2-2 is equal to or greater than 0.1*10⁻⁴ (kJ/m²)²:
$$second elastic energy index ( {E}_{e l a s 2} ) = {G}_{IC} * {( 1 / B )}^{6} * {E}_{a b s} , \qquad ( Eq . 2 - 2 )$$
wherein ‘G_{IC}’ is a facture energy index according to a following Eq. 1, ‘B’ is the brittleness, and ‘E_{abs}’ is the absorption energy:
$$fractured energy index ( {G}_{IC} ) = ( {K}_{IC}^{2} * ( 1 - {v}^{2} ) ) / E , \qquad ( Eq . 1 )$$
wherein ‘K_{IC}’ is a fracture toughness, ‘v’ is Poisson's ratio, and ‘E’ is Young's modulus, and
a third elastic energy index defined by a following Eq. 2-3 is equal to or greater than 2.1 MPa²/m^{0.5};
$$third elastic energy index ( {E}_{e las 3} ) = {G}_{IC} * ( 1 / B ) * {E}_{a b s} , \qquad ( Eq . 2 - 3 )$$
wherein ‘G_{IC}’ is a facture energy index, ‘B’ is the brittleness, and ‘E_{abs}’ is the absorption energy.

19. The display device of claim 17, wherein in the glass article,
a second free volume index defined by a following Eq. 3-2 is equal to or greater than 7.0*10⁻⁸ (kJ/m²)²/K:
$$second free volume index ( {V}_{t 2} ) = {G}_{IC} * {( 1 / B )}^{6} * {E}_{abs} * ( 1 / {T}_{g} ) , \qquad ( Eq . 3 - 2 )$$
wherein ‘T_{g}’ is a glass transition temperature, ‘B’ is the brittleness, and ‘G_{IC}’ is a facture energy index defined by a following Eq. 1:
$$fractured energy index ( {G}_{IC} ) = ( {K}_{IC}^{2} * ( 1 - {v}^{2} ) ) / E , \qquad ( Eq . 1 )$$
wherein ‘K_{IC}’ is a fracture toughness, ‘v’ is Poisson's ratio, ‘E’ is Young's modulus, and ‘E_{abs}’ is the absorption energy, and
a third free volume index defined by a following Eq. 3-3 is equal to or greater than 6.0*10⁻¹⁴ MPa⁴/(m^{2.5}*K³):
$$third free volume index ( {V}_{t 3} ) = {G}_{IC} * ( 1 / B ) * {E}_{abs} * σ * ( 1 / {( {T}_{g} )}^{3} ) , \qquad ( Eq . 3 - 3 )$$
wherein ‘T_{g}’ is a glass transition temperature, ‘G_{IC}’ is a facture energy index, ‘B’ is the brittleness, ‘E_{abs}’ is the absorption energy, and ‘σ’ is the surface strength.

20. The display device of claim 17, wherein the glass article contains SiO₂, Al₂O₃, and at least one metal oxide,
fluxes defined as a ratio of a content of a monovalent metal oxide to a content of a divalent metal oxide in the at least one metal oxide are within a range of 7.0 to 8.5, and
a ratio of a content of Al₂O₃ to a total content of the at least one metal oxide is within a range of 0.3 to 0.4.
